(19) United States
(12) Patent Application Publication
(10) Pub. No.: US 2015/0357151 A1
(43) Pub. Date: Dec. 10, 2015

(54) ION IMPLANTATION SOURCE WITH TEXTURED INTERIOR SURFACES

(71) Applicant: Axcelis Technologies, Inc., Beverly, MA (US)

(72) Inventors: Neil Colvin, Merrimack, NH (US); Tseh-Jen Hsieh, Rowley, MA (US)

(21) Appl. No.: 14/300,692

(22) Filed: Jun. 10, 2014

(51) Int. Cl. H01J 37/08; H01J 37/317; H01J 37/16

(52) U.S. Cl. CPC H01J 37/08; H01J 37/16; H01J 37/3171; H01J 2237/0213

(57) ABSTRACT

An ion implementation system includes an ion source chamber having a textured surfaced to reduce surface film delamination on the interior walls of the ion source chamber. The residual stresses originated from the thermal expansion mismatch due to temperature changes and the tensile residual stress between film and the substrate (liners). The textured feature alters the width to thickness ratio so that it will peel off when it reaches its fracture tensile stress. The machine textures surface increases the mechanical interlocking of the film that builds up on the surface of the ion source chamber, which delays delamination and reduces the size of the resulting flake thereby reducing the likelihood that the flake will bridge a biased component to a ground reference surface and correspondingly increases the life of the ion source.

### BACKGROUND

The present disclosure generally relates to ion implantation systems and, more particularly, to an ion implantation source with a textured surface to reduce delamination of film build-up on the interior surfaces of the ion source.

Ion implantation systems, also known as ion implanters, are widely used to dope semiconductors with impurities in integrated circuit manufacturing and in the manufacture of flat panel displays. In these systems, a dopant gas is introduced into an ion source, which includes a plasma confinement chamber where the gas is excited into an ionized plasma state. An ion beam is extracted from the chamber with a magnetic or electric field and directed onto to a workpiece to implant the workpiece with the dopant element. In computer chip fabrication, for example, the ion beam penetrates the surface of a silicon wafer to create regions with desired conductivity for the fabrication of transistors and other integrated circuit components within the wafer. A typical ion implanter includes an ion source for generating the ion beam, a beamline including a mass analysis magnet for mass resolving the ion beam, and a target chamber containing the semiconductor wafer or other workpiece to be implanted by the ion beam. For high energy implantation systems, an additional acceleration apparatus may be provided between the mass analysis magnet and the target chamber for accelerating the ions to high energies.

Within the plasma containment chamber, high intensity radio frequency (RF) energy is usually utilized to ionize the dopant gas into the plasma state. The dopant gases typically include Phosphorous (P), Arsenic (As), Boron (B), or another readily ionized material. Excitation of the dopant gas to a plasma state generates high temperatures and highly energized ions. While the ion source materials may or may not be conductive in its natural state, all of the dopant materials currently in use become extremely corrosive when cracked (fragmented) into an ionized plasma state. As a result, ion sputter, radical formation and other sources of fouling are known to cause film build-up on the surfaces of the ion source. For example, an ion source chamber manufactured from a refractory metal, such as tungsten, tantalum or molybdenum, may experience hexafluoride decomposition within the plasma confinement chamber in a process known as the halogen cycle resulting in fluoride precipitates condensing into a film on the walls of the chamber and other internal components of the ion source. Stress and delamination of the film tends to result in rapid and destructive erosion of the interior surfaces of the ion source. A need therefor exists to for an improved ion source exhibiting improved durability in the highly corrosive environment of modern ion implementation systems.

### BRIEF SUMMARY

Embodiments of the invention may be realized in an ion implementation system including an ion source having textured interior surfaces to reduce surface film delamination. The textured surfaces increase the mechanical interlocking of the film that builds up on the surface of the plasma confinement chamber, which delays delamination and controls the size of the flakes as the film delaminates, thereby reducing the likelihood that the flake will bridge a biased component to a ground reference surface and correspondingly increases the life of the ion source. An example ion source manufactured from high-purity tungsten includes a chamber that is about 50 mm by 100 mm, a cathode and an opposing repeller with a 9.0 diameter head. An example textured surface includes an approximately 2.0 mm square grid pattern where the grid squares are approximately 0.5 mm deep and separated by approximately 0.5 mm covering the cathode and chamber wall surfaces. The textured surface may be machine cut, laser cut, etched or imparted in any other suitable manner. The specific materials and textured patterns may be varied as a matter of design choice.

The disclosure may be understood more readily by reference to the following detailed description of the various features of the disclosure and the examples included therein.

### BRIEF DESCRIPTION OF THE SEVERAL VIEWS OF THE DRAWINGS

Referring now to the figures wherein the like elements are numbered alike in the several figures:

FIG. 1 is schematic view of an ion implantation system containing an embodiment of an ion source manufactured in accordance with the present disclosure.

FIG. 2 is a perspective view of the exterior of an embodiment of the ion source.

FIG. 3 is a top view of an alternative embodiment of an ion source with the slit plate removed to reveal the textured surfaces on the inner walls of the plasma confinement chamber.

FIG. 4 shows the textured surfaces on the arc slit plate of the ion source.

FIG. 5 shows the textured surfaces on the repeller and an end wall of the plasma confinement chamber.

FIG. 6 shows the textured pattern on a side wall of the plasma confinement chamber of the ion source.

FIG. 7 is a perspective view showing the textured pattern on the repeller of the ion source.

### DETAILED DESCRIPTION

Embodiments of the invention may be realized in an ion implantation system including an ion source with textured interior surfaces to reduce surface film delamination on the interior walls of the plasma confinement chamber and other internal components, such as the slit plate and repeller. U.S. application Ser. No. 14,135,754 entitled “Reduced Trace Metal Contamination Source for an Ion Implantation System” filed Jan. 15, 2014; U.S. Pat. No. 5,497,006 to Sferlazzo et al. and U.S. Pat. No. 5,763,890 to Cloutier et al. describing ion implantation systems are incorporated herein by reference. Application Ser. No. 14,135,754 describes one particular example of an ion implantation system in which embodiments of the present invention may be deployed. Although this is one example system utilizing an embodiment of the invention, the textured ion source described in this disclosure is not limited to this particular environment and may be utilized in plasma ion sources and associated systems generally.

U.S. Pat. No. 5,497,006 describes a plasma ion source having a cathode supported by a base and positioned with respect to a gas confinement chamber for ejecting ionizing electrons into the gas confinement chamber. The cathode of the '006 patent is a tubular conductive body and endcap that partially extends into the gas confinement chamber. A filament is supported within the tubular body and emits electrons that heat the endcap through electron bombardment, thermionically emitting the ionizing electrons into the gas confinement chamber. U.S. Pat. No. 5,763,890 to Cloutier et al also discloses an arc ion source for use in an ion implanter. This particular ion source includes a gas confinement chamber having conductive chamber walls that bound a gas ionization zone. The gas confinement chamber includes an exit opening to allow ions to exit the chamber. A base positions the gas confinement chamber relative to structure for forming an ion beam from ions exiting the gas confinement chamber.

Ion sources that generate ion beams used in existing implanters, typically referred to as arc ion sources, include heated filament cathodes for creating ions that are shaped into an appropriate ion beam for wafer treatment. Conventional ion sources include a plasma confinement chamber having an inlet aperture for introducing a gas to be ionized into plasma and an exit aperture, such as a slit plate, through which the ion beam is extracted. Phosphine gas is one example of a plasma source material. Examples of other typical dopant elements of which the source gas is comprised include Phosphorous (P), Arsenic (As), or Boron (B). When phosphine is exposed to an energy source, such as energetic electrons or radio frequency (RF) energy, the phosphine disassociates forming plasma of positively charged phosphorous (P⁺) ions and hydrogen (H⁺) ions. Typically, the phosphine gas is introduced into the plasma confinement chamber where it exposed to high intensity RF energy to produce the positively charged phosphorous and hydrogen ions. The positively charged ions are then extracted through the exit opening to form the ion beam using an extraction apparatus including energized extraction electrodes. The extracted ion beam is directed onto the workpiece.

The dosage and energy of the implanted ions are varied according to the implantation desired for a given application. Ion dosage controls the concentration of implanted ions for a given semiconductor material. Typically, high current implanters are used for high dose implants, while medium current implanters are used for lower dosage applications. Ion energy is used to control junction depth in semiconductor devices, where the energy levels of the ions in the beam determine the degree of depth of the implanted ions. The continuing trend toward smaller and smaller semiconductor devices requires a beamline construction which serves to deliver high beam currents at low energies. The high beam current provides the necessary dosage levels, while the low energy permits shallow implants. In addition, the continuing trend toward higher device complexity requires careful control over the uniformity of implantation beams being scanned across the workpiece.

The ionization process in the ion source is achieved by excitation of electrons, which then collide with ionizable materials within the plasma confinement chamber. This excitation is typically accomplished using heated cathodes or RF excitation antennas. A cathode is heated so as to emit electrons, which are then accelerated to sufficient energy for the ionization process. An RF antenna generates electric fields that accelerate plasma electrons to sufficient energy for sustaining the ionization process. The antenna may be exposed within the plasma confinement chamber of the ion source, or may be located outside of the plasma chamber, separated by a dielectric window. The antenna is typically energized by an RF alternating current which induces a time varying magnetic field within the plasma confinement chamber. This magnetic field in turn induces an electric field in a region occupied by naturally occurring free electrons within the source chamber. These free electrons accelerate due to the induced electric field and collide with ionizable materials within the plasma confinement chamber, resulting in plasma currents within the chamber, which are generally parallel to and opposite in direction to the electric currents in the antenna. Ions are then extracted from the plasma chamber by one or more energized electrodes creating a strong magnetic or electric field proximate a small exit opening, so as to provide a small cross-section (relative to the size of the workpiece) ion beam.

Batch ion implanters include a spinning disk support for moving multiple silicon wafers through the ion beam. The ion beam impacts the wafer surface as the support rotates the wafers through the ion beam. Serial implanters treat one wafer at a time. The wafers are supported in a cassette and are withdrawn one at time and placed on a support. The wafer is then oriented in an implantation orientation so that the ion beam strikes the single wafer. These serial implanters use beam shaping electronics to deflect the beam from its initial trajectory and often are used in conjunction with coordinated wafer support movements to selectively dope or treat the entire wafer surface.

The plasma confinement chamber and other components of the ion source are currently manufactured from refractory metals and/or graphite. The more commonly used refractory metals include tungsten, molybdenum, tantalum, and graphite due to their high temperature performance and general acceptance by semiconductor chip manufacturers. Corrosion of these materials can occur when ionizing fluorine-based compounds such as BF₃, GeF₄, SiF₄, B₂F₄ and/or oxygen-based compounds such as CO and CO₂, which can dramatically shorten the ion source lifetime and introduce deleterious impurities into the ion beam. For example, ionization of compounds containing fluorine can produce fluorine ions, which can react with exposed surfaces containing the currently employed refractory metal of tungsten, molybdenum, tantalum, graphite, and the like. For example, MoFₓ, WFₓ, TaFₓ, and the like can be formed upon exposure to F⁻ ions, (wherein x is an integer of 1 to 6 in most instances). These materials are corrosive by themselves and the presence of these corrosive materials within the plasma confinement chamber can further propagate a halogen cycle causing these materials to precipitate out of the plasma, condense, build up, and ultimately flake off the interior surfaces of the ion source, which significantly shortens operating lifetimes of this component. When ionizing oxygen-based compounds such as CO and CO₂, the formation of the corresponding refractory oxide can also cause erosion of the ion source components within the plasma chamber including but not limited to the cathode, liners, cathode shield, repeller (i.e., anode or anti-cathode), source aperture slit (i.e., ion source optics plate), and the like, thereby shortening operating lifetimes and requiring replacement.

The ion source gases used may or may not be conductive in nature, but once they are cracked (fragmented) the ionized gas by-product is usually very corrosive. One example is Boron trifluoride (BF₃) which is used as the source gas to generate Boron-11 or BF₂ ion beams. Three free fluorine radicals are generated from an ionized BF₃ molecule. The refractory metals, such as molybdenum and tungsten, are commonly used to construct the ion arc sources in order to sustain its structural integrity at its operating temperature around 700° C. or so. Unfortunately, the refractory fluoride compounds are volatile and have very high vapor pressures even at room temperature. The fluorine radicals formed within the ion chamber attack the tungsten metal (molybdenum or graphite) and form tungsten hexafluoride(WF₆)(molybdenum or carbon fluoride).

WF₆ W⁺+6F or (MoF₆ Mo⁺+6F⁻) [Equation 1]

Tungsten hexafluoride will decompose on hot surfaces such as the chamber walls, repeller and arc slit optics in a process known as the halogen cycle described in equation 1. The fluorine ions tend to precipitate out of the plasma and condense back to the arc chamber walls (liners) and arc slit. A second source of material deposited onto the internal arc chamber components is the indirectly heated cathode (usually tungsten or tantalum) which is used to start and sustain the ion source plasma through thermionic electron emission. The cathode and the repeller (anode or anti-cathode), which are at a negative potential in relation to the arc chamber body, tend to be sputtered by the ionized gases further contribution to the film build-up on the interior walls of the ion source chamber. Stress and delamination of the film results in rapid and destructive erosion of the interior walls of the ion source chamber shortening the life of the ion source.

The surface condition of the interior walls of the ion source chamber plays a key role in the formation of film deposits. London dispersion force describes the weak interaction between transient dipoles or multiples associated with different parts of matter and accounts for a major part of the attractive van der Waals force. Analysis of these processes has led to a better understanding of atomic and molecular adsorption on different metal substrates. The multi-scale modeling integrating first-principles calculations with kinetic rate equation analysis shows that a drastic reduction can occur in the growth temperature, from 1000° C. down to toward the range of 250-300° C.

Addressing the issue of film adhesion involves consideration of the nature of the interfacial region between the deposited material and the liner surface. The typical smooth arc chamber liner and repeller surfaces are susceptible to film delamination that can electrically short the cathode or repeller circuits and cause tool downtime. As the formation of a strong atomic bond within the interfacial region is unlikely to occur; the thermal expansion coefficient differences between the substrate (liner/repeller) and the deposited material, the thermal cycling when transitioning between high power and low power beams, and the dissociation of implant materials residing within the uneven plasma boundary can cause premature failure. The residual stresses in these deposits are of two types: one arises from imperfections during film growth; the other is due to mismatch in the coefficients of thermal expansion between substrate and the deposited film As the film thickness increases, either tensile or compressive stresses will reach threshold levels, and peeling will occur. It has been discovered that delamination of the film build-up on the interior surfaces of the ion source chamber can be significantly delayed or prevented by deliberately roughening all affected surfaces to increase mechanical interlocking.

In a particular embodiment, a series of cross hatches are cut into all the interior surfaces of the ion source including wall liners, arc slit, and repeller (excluding the cathode and its surrounding tubular shaped shield know as a cathode repeller or cathode shield). The physical size of the raised areas was determined by the distance from the repeller to the liner (ground reference) and likewise from the cathode shield to the arc slit (ground reference). In a particular embodiment, a 2 mm by 2 mm grid pattern was chosen to greatly reduce delamination of flakes larger than about 2 mm across. The 0.5 mm width and 0.56 mm depth of the cuts between the raised areas are also selected to control the size of delamination flake. In this particular embodiment, the textured surface may be machine cut with a robotic die cutter. Other suitable texturing techniques may also be utilized, such as laser cutting, etching, and any other suitable texturing technique. In various embodiments, the overall textured pattern may be varied or the pattern may be varied in specific areas. For example, a smaller grid pattern (e.g., 1.0 mm by 1.0 mm) may be imparted on certain areas exposed to high stress, such as the repeller and the area around the slit opening. It will therefore be appreciated that the textured pattern may be selected and varied within the ion source as a matter of design choice.

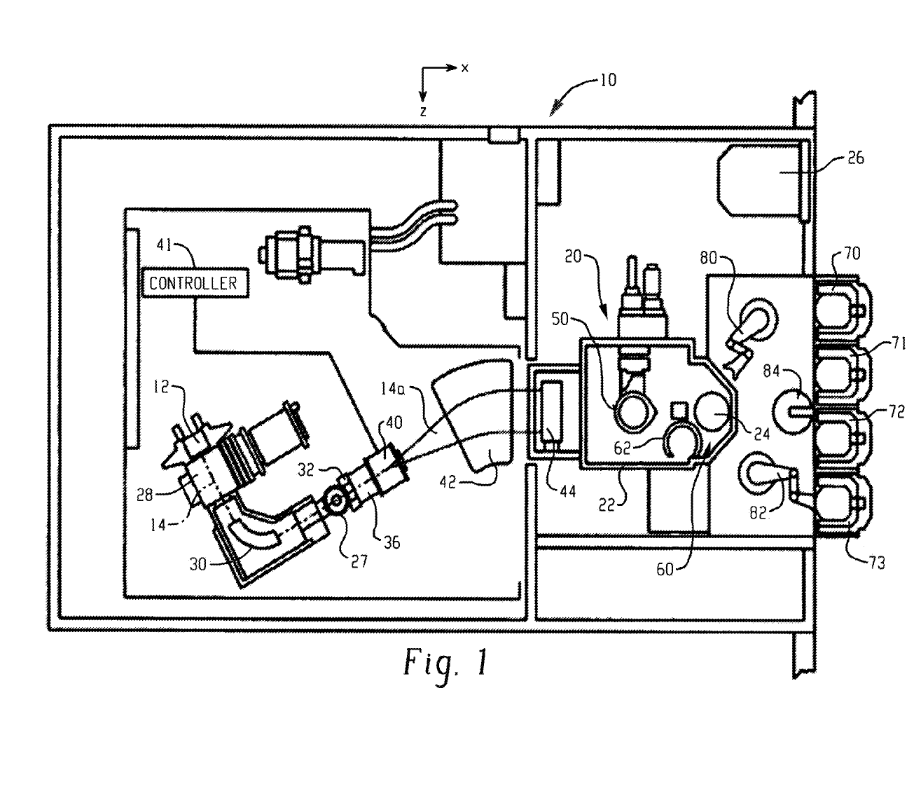

Turning now to the drawings, FIG. 1 is a schematic depiction of an exemplary ion beam implantation system 10 including an ion source 12 having textured interior components. This particular implantation system 10 also includes a vacuum or implantation chamber 22 defining an interior region in which a workpiece 24, such as a semiconductor wafer, is positioned for implantation by an ion beam 14 emitted by the ion source 12. Control electronics indicated generally as the controller 41 monitor and control the ion dosage received by the workpiece 24. A user control console 26 located near the end station 20 accepts operator inputs to the control electronics. One or more vacuum pumps 27 maintain the beamline extending between the ion source 12 and the implantation chamber 22 under low pressure to minimize divergence of the ion beam as it travels through the system.

The ion source 12 includes a plasma confinement chamber defining an interior region into which the dopant source materials are injected. The source materials typically include an ionizable gas or vaporized source material. Ions generated within the plasma chamber are extracted from the chamber by ion beam extraction assembly 28, which includes a number of metallic electrodes for creating an ion accelerating magnetic or electric field.

An analyzing magnet 30 positioned along the beam path 16 bends the ion beam 14 and directs it through a beam shutter 32. Subsequent to the beam shutter 32, the beam 14 passes through a quadrupole lens system 36 that focuses the beam 14. The beam then passes through a deflection magnet 40 which is controlled by the controller 41. The controller 41 provides an alternating current signal to the conductive windings of the magnet 40 which in turn caused the ion beam 14 to repetitively deflect or scan from side to side at a frequency of several hundred Hertz. In one disclosed embodiment, scanning frequencies of from 200 to 300 Hertz are used. This deflection or side to side scanning generates a thin, fan shaped ribbon ion beam 14a.

Ions within the fan shaped ribbon beam follow diverging paths after they leave the magnet 40. The ions enter a parallelizing magnet 42 wherein the ions that make up the beam 14a are again bent by varying amounts so that they exit the parallelizing magnet 42 moving along generally parallel beam paths. The ions then enter an energy filter 44 that deflects the ions downward (“y” direction in FIG. 1) due to their charge. This removes neutral particles that have entered the beam during the upstream beam shaping that takes place.

The ion beam 14a that exits the parallelizing magnet 42 is an ion beam with a cross-section essentially forming a very narrow rectangle. That is, the beam extends in one direction, e.g., has a vertical extent that is limited (e.g. approx. ½ inch [12.7 mm]), and has an extent in the orthogonal direction that widens outwardly due to the scanning or deflecting caused to the magnet 40 to completely cover a diameter of a workpiece such as a silicon wafer. Generally, the extent of the ribbon ion beam 14a is sufficient to, when scanned, implant an entire surface of the workpiece 24, such as a wafer having a horizontal dimension of 300 mm (or a diameter of 300 mm) The magnet 40 will deflect the beam such that a horizontal extent of the ribbon ion beam 14a, upon striking the implantation surface of the workpiece 24 within the implantation chamber 22, will be at least 300 mm.

A workpiece support structure 50 both supports and moves the workpiece 24 (up and down in the “y” direction) with respect to the ribbon ion beam 14 during implantation such that an entire implantation surface of the workpiece 24 is uniformly implanted with ions. Since the implantation chamber interior region is evacuated, workpieces must enter and exit the chamber through a loadlock 60. A robotic arm 62 mounted within the implantation chamber 22 automatically moves wafer workpieces to and from the loadlock 60. A workpiece 24 is shown in a horizontal position within the load lock 60 in FIG. 1. The arm moves the workpiece 24 from the load lock 60 to the support 50 by rotating the workpiece through an arcuate path. Prior to implantation, the workpiece support structure 50 rotates the workpiece 24 to a vertical or near vertical position for implantation. If the workpiece 24 is vertical, that is, normal with respect to the ion beam 14, the implantation angle or angle of incidence between the ion beam and the normal to the workpiece surface is zero degrees.

In a typical implantation operation, undoped workpieces (typically semiconductor wafers) are retrieved from one of a number of cassettes 70-73 by one of two robots 80, 82 which move a workpiece 24 to an aligner 84, where the workpiece 24 is rotated to a particular orientation. A robot arm retrieves the oriented workpiece 24 and moves it into the load lock 60. The loadlock closes and is pumped down to a desired vacuum, and then opens into the implantation chamber 22. The robotic arm 62 grasps the workpiece 24, brings it within the implantation chamber 22 and places it on an electrostatic clamp or chuck of the workpiece support structure 50. The electrostatic clamp is energized to hold the workpiece 24 in place during implantation. Suitable electrostatic clamps are disclosed in U.S. Pat. Nos. 5,436,790, issued to Blake et al. on Jul. 25, 1995 and 5,444,597, issued to Blake et al. on Aug. 22, 1995, both of which are assigned to the assignee of the present invention. Both the '790 and '597 patents are incorporated by reference.

After ion beam processing of the workpiece 24, the workpiece support structure 50 returns the workpiece 24 to a horizontal position and the electrostatic clamp is de-energized to release the workpiece. The arm 62 grasps the workpiece 24 after such ion beam treatment and moves it from the support 50 back into the load lock 60. In accordance with an alternate design the load lock has a top and a bottom region that are independently evacuated and pressurized and in this alternate embodiment a second robotic arm (not shown) at the implantation station 20 grasps the implanted workpiece 24 and moves it from the implantation chamber 22 back to the load lock 60. From the load lock 60, a robotic arm of one of the robots moves the implanted workpiece 24 back to one of the cassettes 70-73 and most typically to the cassette from which it was initially withdrawn.

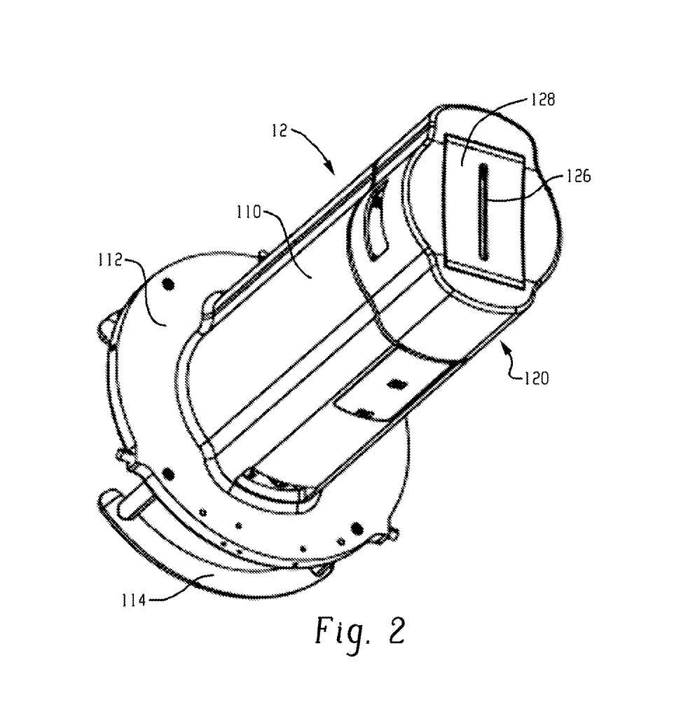

As shown in FIG. 2, the ion generating source 12 includes a source block 110 supported by a flange 112 having handles 114 by which the source 12 can be removed from the implanter. The source block 110 supports a plasma arc chamber shown generally at 120. The high-density plasma arc chamber 120 has an elongated, generally elliptically shaped exit source aperture 126 in a plate 128 through which ions exit the source. Additional details concerning one prior art ion source are disclosed in U.S. Pat. No. 5,026,997 to Benveniste et al. assigned to the assignee of the present invention and which is incorporated by reference. As ions migrate from the arc chamber 120, they are accelerated away from the chamber 120 by electric fields set up by the beam extraction assembly positioned relative to the exit aperture.

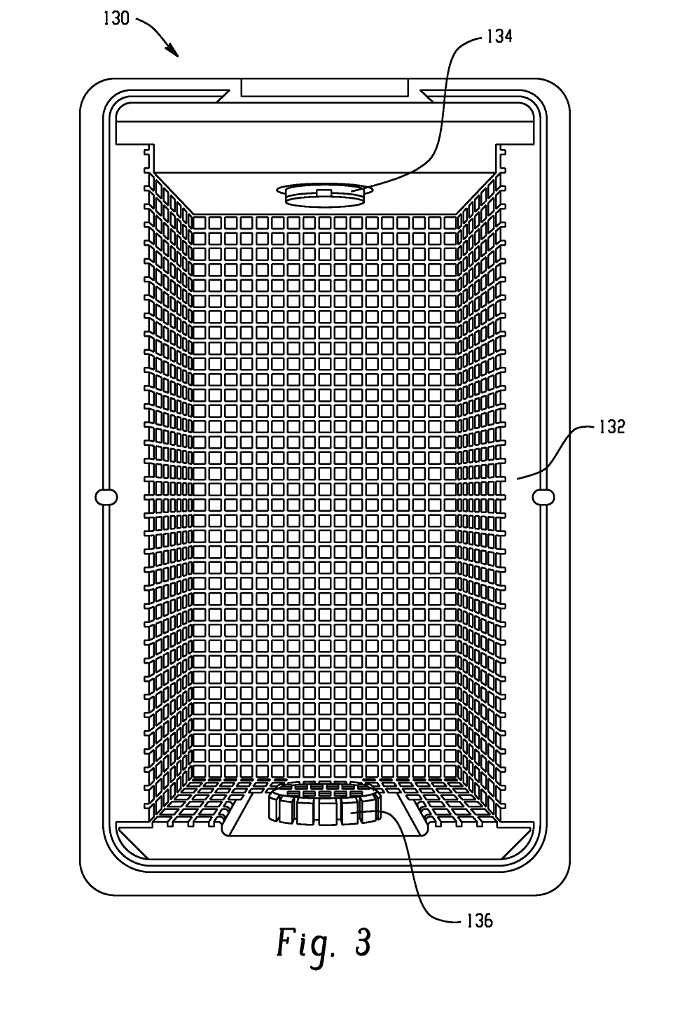

FIG. 3 is a top view of an alternative embodiment of an ion source 130, which includes a plasma confinement chamber 132, a cathode 134, and a repeller 136 (also referred to as the anode or anti-cathode). In this view the slit plate has been removed to reveal the textured surfaces on the inner walls of the plasma confinement chamber 132. The plasma confinement chamber in this particular embodiment is somewhat more rectangular than the chamber 120 shown in FIG. 2 while serving the same basic function.

The interior walls of the confinement chamber 132 and the repeller 136 are textured with square grid pattern to inhibit delamination of the film build-up on these surfaces. In this embodiment, which is shown substantially to scale in FIGS. 3-5, the chamber 132 is about 50 mm by 100 mm and the head in the repeller is about 9.0 mm in diameter. The plasma confinement chamber 132 in this particular embodiment is manufactured from highly pure (99.95%) tungsten, while the repeller 136 is manufactured form highly pure (99.90%) tantalum. The textured surfaces includes an approximately 2.0 mm square grid pattern where the grid squares are approximately 0.5 mm deep and separated by approximately 0.5 mm covering the repeller and substantially all of the interior wall surfaces of the plasma confinement chamber. This textured pattern is well suited to being machine cut although any suitable texturing technique may be utilized.

In this particular embodiment, the cathode 134, which is partially covered by a cathode shield, is not textured. However, the cathode shield could be textured if desired, for example by pressing or otherwise forming the pattern into the shield, which is typically manufactured from a relatively thin material.

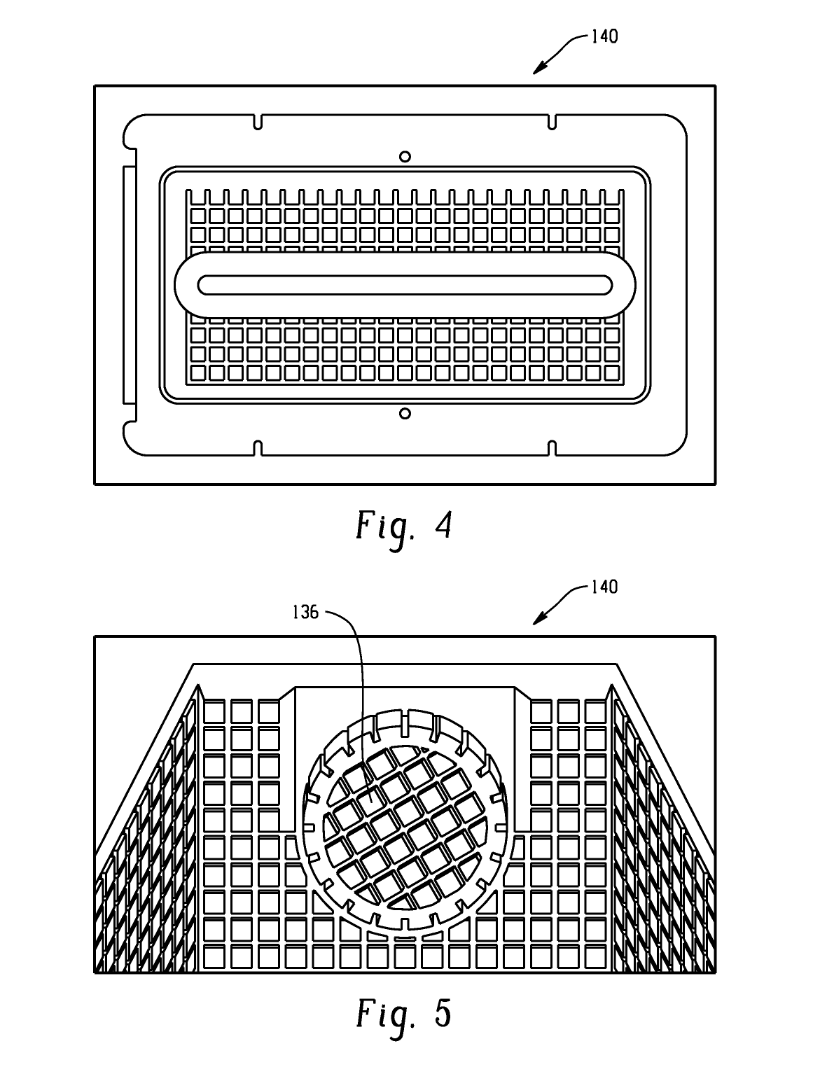

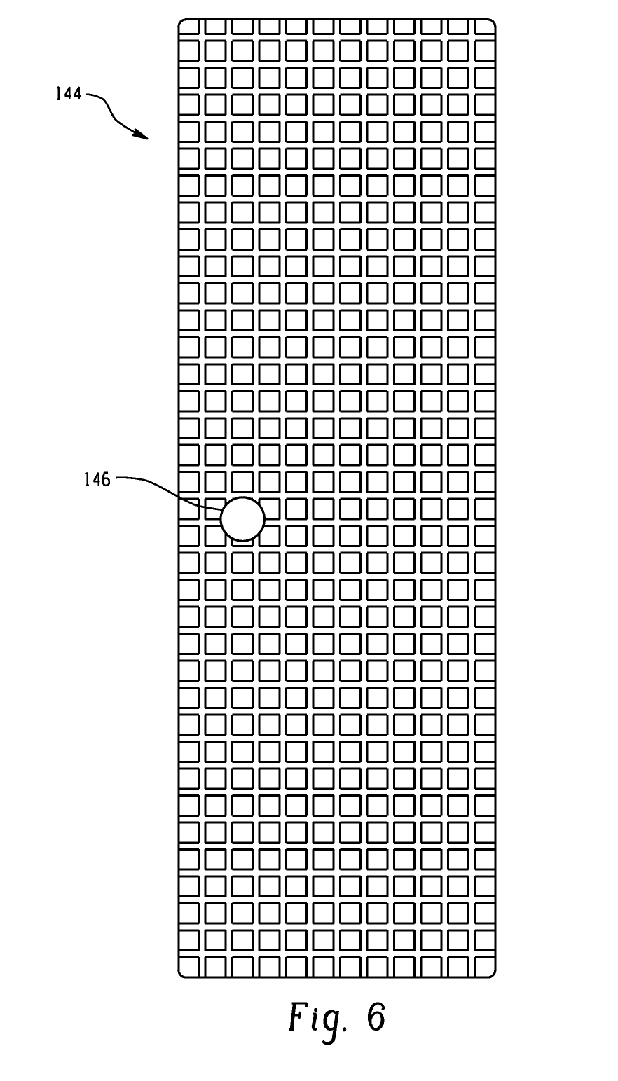

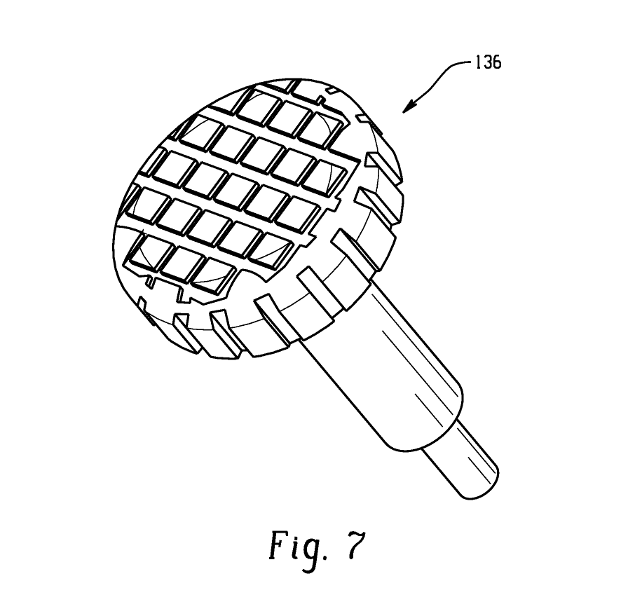

FIG. 4 shows the textured surfaces on the slit plate 140, which fits onto the portion of the chamber shown in FIG. 3. The slit plate forms part of the plasma confinement chamber and, in this particular embodiment, is manufactured from highly pure (99.95%) tungsten consistent with the remainder of the chamber. The ion beam is extracted from the plasma chamber through the slit plate, typically by magnetic or electric field extraction. FIG. 5 shows the end wall 142 of the plasma confinement chamber that supports the repeller 136 showing that the repeller and the end wall are covered with the square grid textured pattern. FIG. 6 shows the textured pattern on a side wall 144 of the plasma confinement chamber including specific dimensions (stated in mm) for this particular embodiment. The side will 144 includes a source material port 146 for injecting a dopant source material into the plasma source chamber. FIG. 7 shows the textured pattern on the repeller of the ion source. The same 2 mm by 2 mm square textured pattern is applied to the slit plate, the repeller, and the interior walls of the chamber.

Although all of the interior walls of the plasma confinement chamber 132 (including the slit plate 140) and the repeller 134 are substantially covered with the same textured pattern in the particular embodiment depicted, it should be appreciated that only a portion of these components could be textured, that a different texturing pattern could be applied, and that a different texturing pattern could be applied to certain components, surfaces, or areas. For example, only the interior walls, slit plate, and/or repeller could be textured if desired. In addition, the textured pattern could be varied overall or on certain components or portions of components. To provide one of many possible examples, a 1.0 mm grid could be applied to high stress areas such as the repeller and/or near the opening of the slit plate if desired. Other potential variations and modification will be evident to those skilled in the art.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An ion implantation system having an ion source, the ion source comprising:
a plasma confinement chamber having interior walls;
a cathode and a cathode shield at least partially covering the cathode are supported within the plasma confinement chamber;
a repeller supported within the plasma confinement chamber;
wherein at least the cathode shield carries a textured pattern to inhibit delamination of film buildup thereon .

2-8. (canceled)

9. An ion source for an ion implantation system, comprising:
a plasma confinement chamber having interior walls;
a cathode and a cathode shield at least partially covering the cathode are is-supported within the plasma confinement chamber;
a repeller supported within the plasma confinement chamber;
wherein at least the cathode shield carries a textured pattern to inhibit delamination of film build-up on the surfaces.

10-15. (canceled)

16. A plasma confinement chamber for an ion source for an ion implantation system comprising a cathode shield at least partially covering a cathode supported within the plasma confinement chamber; the cathode shield carrying a textured pattern to inhibit delamination of film build-up on the surfaces.

17-20. (canceled)
